(19) United States
(12) Patent Application Publication
(10) Pub. No.: US 2023/0160934 A1
(43) Pub. Date: May 25, 2023

(54) Grounding Assurance and Voltage-to-Patient Detection for Patient Safety

(71) Applicant: NxStage Medical, Inc., Lawrence, MA (US)

(72) Inventor: Patrick MILLER, Waltham, MA (US)

(73) Assignee: NxStage Medical, Inc., Lawrence, MA (US)

(21) Appl. No.: 17/976,118

(22) Filed: Oct. 28, 2022

Related U.S. Application Data
(60) Provisional application No. 63/281,873, filed on Nov. 22, 2021.

(51) Int. Cl. G01R 19/165; G01R 19/22; H02H 3/00; H02H 1/00

(52) U.S. Cl. CPC G01R 19/1659; G01R 19/22; H02H 3/00; H02H 1/0007

(57) ABSTRACT

A system for ensuring that electrically powered medical equipment is properly grounded includes a current sensor that senses current flowing within a ground connection conductor (e.g., leakage current) for the medical equipment. The sensor may operate based on induced current. Measured current is converted to a voltage value, and the voltage value is analyzed by a processor to determine whether current is present in the ground connection conductor. If no current is present, the ground connection conductor may be faulty. If current is present, the system can also identify voltage-to-patient fault conditions.

### CROSS-REFERENCE TO RELATED APPLICATIONS

This application claims priority to and the benefit of U.S. Provisional Patent Application No. 63/281,873 filed Nov. 22, 2021 which is hereby incorporated by reference in its entirety.

### BACKGROUND

The use of electrically powered medical devices or equipment connected to a patient is common in modern medicine. Along with the benefits these devices provide, they also can create a potential hazard of electric shock to the patient. Electric shock can be caused by current (referred to as leakage current) flowing through the patient's heart, for instance, creating ventricular defibrillation, which a medical device may induce in an earthed patient or sink to earth if the patient is in contact with another source of electricity.

As illustrated in FIG. 1, a patient 10 is undergoing or about to undergo treatment with medical equipment 12. The grounded power cord 13 of medical equipment 12 (e.g., a so-called three-pronged cord) may be plugged into a grounded electrical outlet 14, which may provide electrical power at 120 Volt alternating current (AC) in the U.S. or 230 Volt AC elsewhere. (The amount of leakage current in the system will vary with line voltage.) The medical equipment 12 may be, for example, a blood treatment device, a hemodialysis treatment device, a peritoneal dialysis treatment device, a hemofiltration treatment device, or any other device that conveys blood and/or other fluids between the patient and the medical equipment 12. Thus, the patient 10 is connected to the medical equipment 12 (e.g., blood treatment device) by one or more hollow fluid lines 16 that can convey blood and/or other fluids between the patient 10 and the blood treatment device. (Although a single fluid line 16 is illustrated, more fluid lines may be present, depending on the specific nature of the medical treatment and the medical equipment 12 being used.)

When it is filled with a conductive fluid such as blood, saline or dialysate, the fluid line 16 creates a conductive pathway between the patient 10 and the medical equipment 12. Furthermore, when an alternating current (AC) is flowing in a conductive pathway, which could be a fluid line 16 filled with conductive fluid, the fluid line may be capacitively coupled to a conductive surface next to or near the fluid line. When the fluid line is part of medical equipment 12 that is coupled to a patient 10 and the conductive surface is at ground potential, the capacitive coupling of the fluid line 16 could cause leakage current 18 to flow through the patient 10 when the patient is electrified with alternating current.

Another potential risk associated with such electrically powered medical devices or equipment is a voltage-to-patient fault, which occurs when a source passes through the patient connection and finds its way to ground 20 through the medical equipment 12. Typically, this is expected to be through the ground connection conductor 22 within the grounded power cord 13 of the medical equipment 12.

Furthermore, different electrically powered medical devices have different ratings and requirements, depending on how they are used and/or where their components (referred to as “applied parts”) may contact the patient's body. For example, a type BF (“body floating”) rating generally is used for medical devices in which the applied parts make medium or long-duration conductive contact with the patient 10, but which are not electrically connected directly to the patient's heart. These may include, for example, blood pressure monitors, incubators, ultrasound equipment, etc. For BF devices, the amount of leakage current they are permitted to generate is 100 μA under normal conditions (NC) and 500 μA under single fault conditions (SFC).

On the other hand, a type CF (“cardiac floating”) rating is used for medical devices whose applied parts may, in fact, come into direct electrical contact with the patient's heart. These include medical devices such as those listed above, e.g., dialysis machines, blood filtration devices, etc. For CF devices—given their potential for direct electrical contact with the patient's heart—the requirements are more stringent. In particular, the amount of leakage current CF devices are permitted to generate is 10 μA under normal conditions (NC) and 50 μA under single fault conditions (SFC).

To prevent the patient 10 from being harmed by system leakage currents, a ground connection conductor must be provided between the medical equipment 12 and ground 20. As noted above, this is typically the ground connection conductor 22 within the grounded power cord 13 of the medical equipment 12, i.e., the conductor that terminates in the third, ground prong of a three-prong plug.

In a grounded CF system, the leakage current flowing through the ground connection conductor 22 in normal condition will be less than 50 μA. On the other hand, in the patient-to-ground SFC test condition (e.g., under lifted ground conditions), the patient 10 becomes the ground source, and 50 μA will be the leakage current limit. Hence, for a grounded CF system, the leakage current flowing through the ground connection conductor 22 is expected to be between 10 μA and 50 μA. (Although it is possible to have leakage current less than 10 μA, such levels generally do not pose a safety risk to a patient and the ground connection conductor 22 is not vital.)

In a grounded BF system, the leakage current will flow to ground 20 along the same ground connection conductor 22 as in a CF system. As noted above, however, the current limits are higher than for a CF system. Hence, a BF system could have leakage currents up to 500 μA, and in an SFC condition, the patient 10 becomes the ground source. Hence, for a grounded BF system, the leakage current range is expected to be between 10 μA and 500 μA. (It should be noted that under the 60601 standard, which is assumed to be at 240 VAC, this limit is 500 μA. In the U.S., where mains voltage is 120 VAC, the requirement is that it be less than 300 μA.)

Given the importance to patient safety of the ground connection conductor 22, it is beneficial to be able to verify the integrity of the ground connection conductor 22. Additionally, it is beneficial to be able to identify a voltage-to-patient fault and respond appropriately to protect the patient 10. Considering the current limits addressed above, for any medical device system to be monitored, leakage current expected to be present should be between 10 μA and 500 μA.

### SUMMARY

Disclosed herein are a device and associated methodology for safeguarding a patient undergoing treatment using electrically powered medical equipment, where the medical equipment is grounded. In general, the device senses current flowing in a ground connection conductor by which the medical equipment is grounded and generates an input signal to a processor based on and indicative of the current sensed in the ground connection conductor. If the sensed current is less than or equal to a low threshold (which indicates failure of the ground connection), an alarm is issued and power to the medical equipment may be terminated. (As a preliminary check, the device may determine whether the medical equipment is powered on by sensing current flowing in a load line that provides electrical power to the medical equipment.) If the sensed current is initially within proper levels, the device may proceed to monitor for voltage-to-patient faults, also by monitoring current levels within the ground connection conductor. Threshold values will depend on, and may be switched according to, a class rating of the medical equipment.

In general, the device suitably is capable of accepting AC currents from 0 to 500 μA as an expected operating range and suitably is capable of determining a ground disconnection when the measured current drops below 10 μA. The device and associated methodology suitably are able to determine initial operating state and determine appropriate alarm threshold. If initial leakage current is between 10 μA and 50 μA, then one threshold setting would be 50 μA (this would be considered a CF applied part). If the initial leakage current measured is between 50 μA and 300 μA, then the threshold setting would be 500 μA (this would be considered a BF applied part). Further, if the initial current reading is less than 10 μA, then either the system being monitored is not suitable for use with the device or there is a ground continuity fault already present that needs to be addressed. Further still, the device suitably is able to determine whether or not a system is plugged in and powered before it makes the initial reading.

According to one aspect, a grounding continuity assurance device is disclosed for use in connection with an electrically powered medical device that has a ground connection. The grounding continuity assurance device includes a first current sensor configured to detect and produce a first sensor output signal in response to and indicative of electrical current in a ground connection conductor by which the electrically powered medical device is grounded; and a processor configured to receive a first processor input signal corresponding to the first sensor output signal. The processor is configured to analyze the first processor input signal and issue a first alarm signal if the value of the first processor input signal is less than or equal to a predetermined low threshold value corresponding to a minimum level of electrical current expected to be present in the ground connection conductor during normal operation of the electrically powered medical device.

In embodiments, the processor may be further configured to analyze the first processor input signal and issue a second alarm signal if the value of the first processor input signal is greater than or equal to a predetermined high threshold value, which corresponds to a maximum level of electrical current expected to be present in the ground connection conductor during normal operation of the electrically powered medical device. Furthermore, the low threshold value and the high threshold value may correspond to a rating of the electrically powered medical device based on whether the electrically powered medical device makes direct electrical contact with a patient's heart. Still further, the low threshold value and the high threshold value may be switchable to different values to facilitate use of the grounding continuity assurance device with electrically powered medical devices having different ratings.

Moreover, in embodiments, the first sensor output signal may constitute an electrical current and the first processor input signal may constitute voltage. In such embodiments, the device may further include signal-processing circuitry configured to receive as input thereto the first sensor output signal and to output, as the first processor input signal, a voltage corresponding to the first sensor output signal. For example, the first current sensor may be a transformer with a ring-shaped, magnetic flux-conducting core; a primary conductor coil formed by a portion of the ground connection conductor being looped around a first portion of the magnetic flux-conducting core; and a secondary conductor coil looped around a second portion of the magnetic flux-conducting core, where the first sensor output signal constitutes electrical current induced in the secondary conductor coil by alternating current flowing along the ground connection conductor. To process the first sensor output signal, the signal-processing circuitry may include a gain stage and a rectification and peak-picking stage.

Further still, in embodiments, a second current sensor may be included that is configured to detect and produce a second sensor output signal in response to and indicative of electrical current in an AC load line that provides electrical power to the electrically powered medical equipment. For such embodiments, the processor may be further configured to receive a second processor input signal corresponding to the second sensor output signal; and to analyze the second processor input signal to determine whether the electrically powered medical equipment is powered on before analyzing the first processor input signal to determine whether the value of the first processor input signal is less than or equal to the predetermined low threshold value. The device processor may further be configured to analyze the first processor input signal and issue a third alarm signal if the value of the first processor input signal corresponds to a voltage-to-patient fault condition.

In embodiments, the grounding continuity assurance device may be a stand-alone device that is configured to be interposed between a source of electrical power and the electrically powered medical equipment, with electrical current passing through the grounding continuity assurance device between the source of electrical power and the electrically powered medical equipment. Alternatively, the grounding continuity assurance device may be integral with the electrically powered medical equipment.

Suitably, the grounding continuity assurance device may be configured to terminate or prevent the flow of electricity to the electrically powered medical device if the value of the first processor input signal is less than or equal to the predetermined low threshold value; if the value of the first processor input signal is greater than or equal to the predetermined high threshold value; and/or if the value of the first processor input signal (subsequently) corresponds to a voltage-to-patient fault condition.

In another aspect, disclosed herein is a method for assuring safety of a patient being treated with electrically powered medical equipment that is grounded via a ground connection conductor. The method includes sensing current level in the ground connection conductor in a first sensing phase; and issuing a first alarm signal if the current level in the ground connection conductor during the first sensing phase is less than or equal to a predetermined low threshold value that corresponds to a minimum level of electrical current expected to be present in the ground connection conductor during normal operation of the electrically powered medical device. In embodiments, the method responds to a voltage-to-patient fault condition.

A device in accordance with this disclosure may provide several benefits, including providing continuous ground integrity monitoring (which is not the case normally). It may also monitor for other fault conditions in the patient environment that are indicated by an increase in leakage current. The device could be used for any system where leakage current monitoring (e.g., for fire protection) may be beneficial.

The device can be configured with different threshold criteria depending on the type of medical equipment it is being used to monitor, or the thresholds could be switchable depending on use. Such ability to switch thresholds would allow the device to be used in different locations and with different medical equipment. In embodiments, the device response to a fault condition may further include issuing a second alarm signal if the current level in the ground connection conductor during the first sensing phase is greater than or equal to a predetermined high threshold value that corresponds to a maximum level of electrical current expected to be present in the ground connection conductor during normal operation of the electrically powered medical device.

Furthermore, embodiments may include, in a second sensing phase after the first sensing phase, sensing current level in the ground connection conductor and issuing a third alarm signal if the current level in the ground connection conductor during the second sensing phase corresponds to a voltage-to-patient fault condition. Before the first sensing phase, current level may be sensed in a load line that provides electrical power to the medical equipment to determine whether the medical equipment is powered on and requires monitoring.

Further still, embodiments of the method may include terminating or preventing the flow of electricity to the electrically powered medical device if the value of the first processor input signal is less than or equal to the predetermined low threshold value; if the value of the first processor input signal is greater than or equal to the predetermined high threshold value; and/or if the current level in the ground connection conductor during the second sensing phase (mains) are present.

An internally integrated device could be tied into the onboard equipment alarm system to enable isolation of the patient from the system (e.g., in connection with hemodialysis equipment).

Conversely, an external, stand-alone device could have its own alarm system, or be integrated into the medical equipment wirelessly or through a hardwire connection. An external device could have means to isolate the system from the mains power in the event of a ground fault.

### BRIEF DESCRIPTION OF THE DRAWINGS

Embodiments will hereinafter be described in detail below with reference to the accompanying drawings, wherein like reference numerals represent like elements. The accompanying drawings have not necessarily been drawn to scale. Some of the figures may have been simplified by the omission of selected features for the purpose of more clearly showing other underlying features. Such omissions of elements in some figures are not necessarily indicative of the presence or absence of particular elements in any of the exemplary embodiments, except as may be explicitly disclosed in the corresponding written description.

FIG. 1 illustrates generally an example of a patient connected to medical equipment as known in the art;

FIG. 2 is a schematic, high-level diagram illustrating an example of a system for verifying the integrity of a ground connection conductor according to embodiments of the disclosure;

FIGS. 3A, 3B, and 3C are schematic diagrams illustrating different ways/locations in which to implement or deploy the system for verifying the integrity of a ground connection conductor shown in FIG. 2;

FIG. 4 is a schematic diagram illustrating one embodiment of a current sensor used in the system for verifying the integrity of a ground connection conductor shown in FIG. 2;

FIG. 5 is a circuit diagram illustrating components of a signal conditioning and amplification circuit according to embodiments of the disclosure; and

FIGS. 6A and 6B illustrate flowcharts demonstrating operational logic of a system according to embodiments of the disclosure.

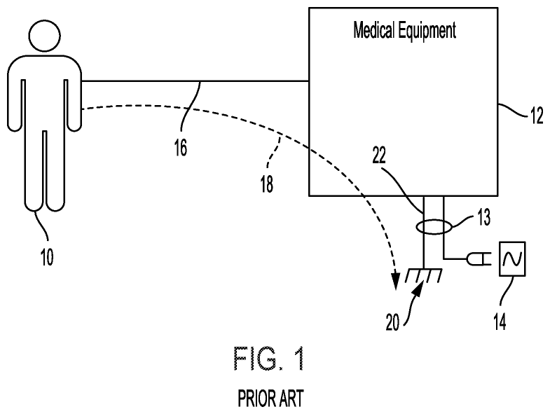

### DETAILED DESCRIPTION

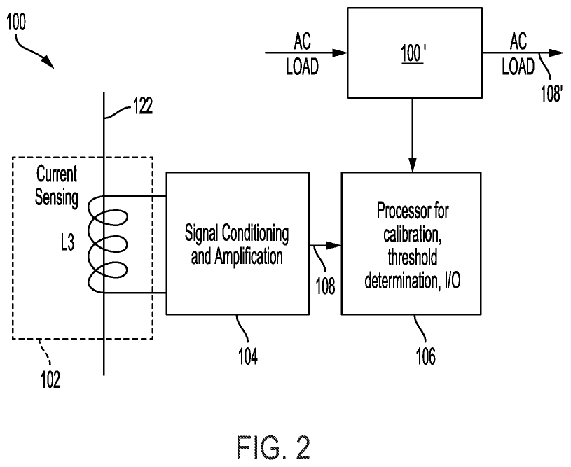

An exemplary embodiment of a system 100 for verifying the integrity of a ground connection conductor 122 is illustrated at a “high level” in FIG. 2. In general, the system 100 includes a current sensor 102 (that may include a coil designated at L3) that detects alternating current flowing along ground connection conductor 122; signal conditioning and amplification circuit 104; and a processor/instructions 106 (referred to as “processor 106” for short), which receives and analyzes the output signal 108 from the signal conditioning and amplification circuit 104.

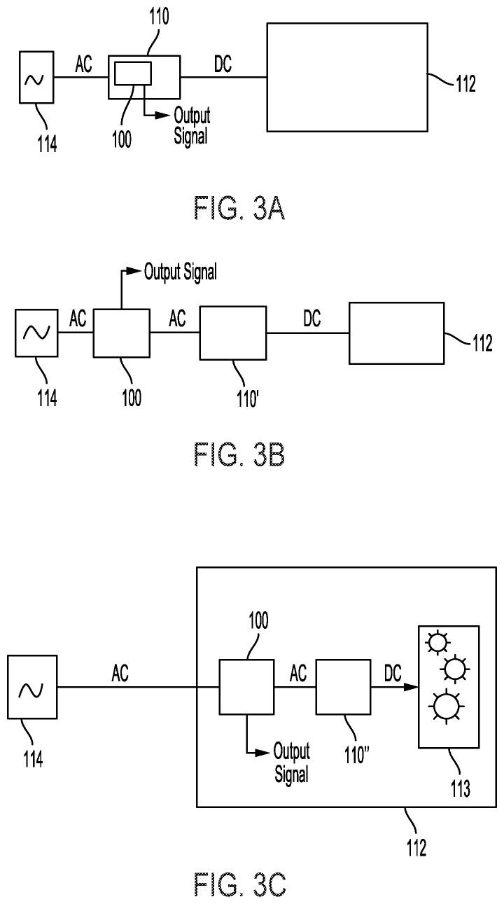

As illustrated in FIGS. 3A, 3B, and 3C, the system 100 could be implemented in various ways. For example, as illustrated in FIG. 3A, the system 100 could be integrated with an external power adapter 110, which plugs into an electrical outlet 114 and converts AC current from the electrical outlet 114 into DC current that is used to power the medical equipment 112. Alternatively, as illustrated in FIG. 3B, the system 100 could be provided as a “stand-alone” device, which plugs into the electrical outlet 114 and to which a more standard or typical power adapter 110′ (which converts AC current to DC current) connects. And further still, as illustrated in FIG. 3C, the system 100 could be integrated into the medical equipment 112 itself, located to receive AC current from electrical outlet 114 and upstream of internal power supply 110″ (which receives AC current and provides DC current to various components 113 within the medical equipment 112).

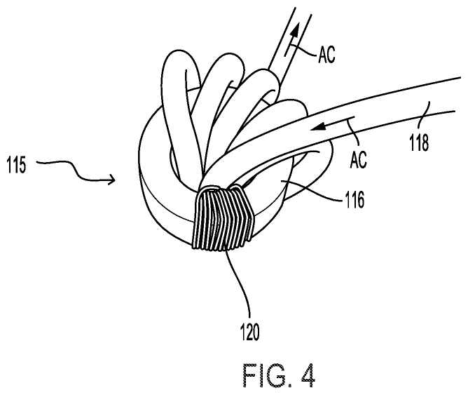

An embodiment of the sensing element 115 of the current sensor 102 is illustrated in FIG. 4. In general, the sensing element is constructed as a transformer, which includes a ring-shaped, core 116, which may be magnetic flux-conducting ferrite or iron core with primary conductor coil 118 looping around the core 116 at one location and a secondary conductor coil 120 looping around the core 116 at another location. The primary conductor coil 118 constitutes part of the current-conducting pathway for the ground connection conductor 122, and the secondary conductor coil 120 carries induced current that is an input into to the signal conditioning and amplification circuit 104.

As will be understood by those of skill in the art, current flowing within the loops of the primary conductor coil 118 establishes a magnetic field that extends along the portion of the core 116 around which the loops of the primary conductor coil 118 are wrapped. The direction in which that magnetic field extends depends on the direction in which the current is flowing within the primary conductor coil 118, in accordance with a right-hand rule, and the strength of that magnetic field will be proportional to the number of loops that are wrapped around the core 116. Magnetic flux will, in turn, circulate along the core 116 and through the loops of the secondary conductor coil 120, with the direction of circulation likewise depending on the direction in which the electrical current is flowing relative to the portion of the core 116 around which the loops of the primary conductor coil 118 are wrapped.

For direct current flowing within the primary conductor coil 118, the magnetic field will be constant, and there will be no effect on the secondary conductor coil 120. On the other hand, if alternating current (AC) flows within the primary conductor coil 118, as will be the case for leakage current, the magnitude and direction of the magnetic field established by the alternating current and extending along the core 116 will vary sinusoidally with the alternating current, as will the magnitude and direction of the magnetic flux extending along the core 116 and passing through the loops of the secondary conductor coil 120. Furthermore, as the magnetic flux passing through the loops of the secondary conductor coil 120 varies in magnitude and direction, voltages (emf) will be induced across the secondary conductor coil 120 in accordance with Faraday's law of induction. The magnitude of the induced voltage will be proportional to the time rate of change in magnetic flux through the secondary conductor coil 120 as well as the number of loops in the secondary conductor coil 120. Additionally, the ratio of the voltage induced across the secondary conductor coil 120 to the voltage drop across the primary conductor coil 118 (associated with current flowing along the primary conductor coil 118) will be the same as the ratio of the number of loops in the secondary conductor coil 120 to the number of loops in primary conductor coil 118. Furthermore, the induced voltage will act in a direction that causes induced current to flow along the secondary conductor coil 120 in a direction such that the magnetic field associated with the induced current opposes the time-varying nature of the magnetic flux through the secondary conductor coil 120, in accordance with Lenz's law.

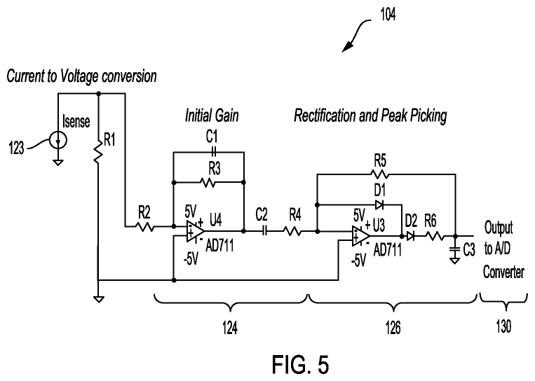

As illustrated in FIG. 5, the current induced in the secondary conductor coil 120 is used as a current-source input 123 to the signal conditioning and amplification circuit 104. In general, the signal conditioning and amplification circuit 104 converts the sensed induced current from the secondary conductor coil 120 to an input voltage across resistor R1 to virtual ground. The input voltage may be scaled via an initial gain stage 124, the AC output of which is then rectified by rectification and peak-picking stage 126. The rectification and peak-picking stage 126 also identifies peak voltage of the AC output from the initial gain stage 124. Final gain and output stage 130 supports a 0 to Vcc input into an analog-to-digital converter (not illustrated). The output of the analog-to-digital converter is then processed via the processor 106 to assess the integrity of the ground connection conductor 122, as addressed more fully below.

The circuit in FIG. 5 includes various circuit elements, including resistors, capacitors, and diodes. The resistors are labeled with the letter “R” and a number to identify distinct resistors, but the number does not indicate the numerical value of the resistance of the resistor. Similarly, capacitors are identified with the letter “C” and a number to identify distinct capacitors, but the number does not necessarily represent a numerical value of the capacitance of any particular capacitor. The diodes are identified with the letter “D” and a number to identify distinct diodes, but the number does not indicate any numerical value of properties of the diode. FIG. 5 also includes various operational amplifiers (“op-amps”) which are designated with AD711, which is just one example of an operational amplifier, but it will be understood that many other types of op-amps are contemplated and may be used, and AD711 is merely an example.

For leakage current of the magnitude addressed above for BF and CF systems, i.e., between 10 μA to 500 μA, suitable values for the components used in the signal conditioning and amplification circuit 104, in an exemplary embodiment, are as follows:
R1=50Ω;
R2=1k Ω
R3=40k Ω
R4=100k Ω
R5=1000k Ω
R6=220Ω
C1=1 nf
C2=10 μf
C3=10 μf
D1, D2 are diodes (e.g., model 1 N4148, in an exemplary embodiment).

Furthermore, a secondary load-sensing subsystem 100′ (FIG. 2) that is similar to the current sensor 102 and signal conditioning and amplification circuit 104 may be provided to monitor and/or sense current in the AC load line that provides electrical power to the medical equipment 112, to determine whether the medical equipment 112 is powered on and requires monitoring or whether the medical equipment 112 is powered off and therefore does not need monitoring. The sensing element (core and conductor coil loops) of the secondary load-sensing subsystem 100′ are sized/designed in view of the anticipated AC loads for powering the medical equipment 112, as are the components of the signal conditioning and amplification circuitry of the secondary system (i.e., op-amps, resistors, capacitors, and diodes). Output signal 108′ of the secondary subsystem 100′ will also be provided to an analog-to-digital converter (not illustrated), the output of which is processed via the processor 106—along with the output of the system 100—as part of the process for assessing the integrity of the ground connection conductor 122, as addressed more fully below.

As addressed above, the ground connection conductor 122 protects a patient from leakage current by providing a current pathway from the equipment to ground. Additionally, the ground connection conductor 122 protects the patient in case of a voltage-to-patient fault, also by providing a current pathway to ground. Therefore, the system 100 can be used to identify a voltage-to-patient fault condition (in addition to identifying whether the ground connection conductor 122 is compromised) by monitoring for an increase in current measured as flowing along the ground connection conductor 122. In this regard, for CF applied parts, the rating standard requires a single-fault-condition to cause less than 50 μA of current through the ground connection conductor 122, and for a BF applied part, the rating standard requires a single-fault-condition to cause less than 500 μA of current through the ground connection conductor 122. Because these current levels are within the expected operating range of the device, if voltage-to-patient monitoring is a desired feature, then the operational logic of the system needs to account for the operational state of the medical equipment 112.

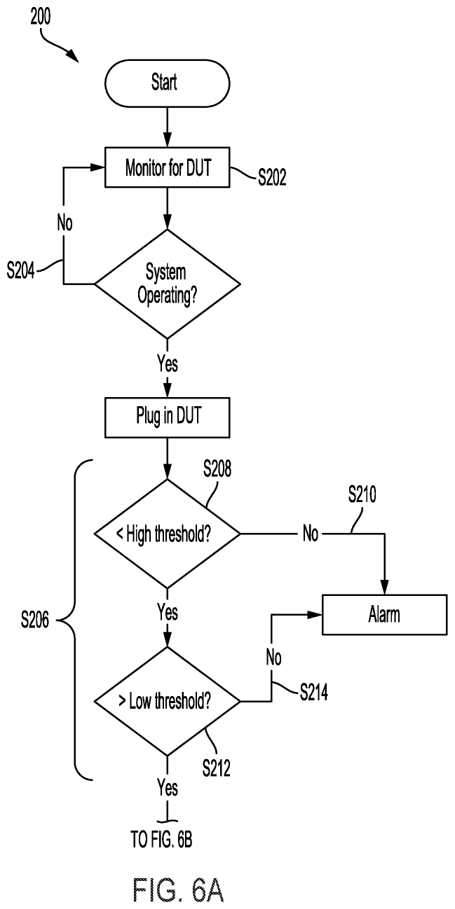

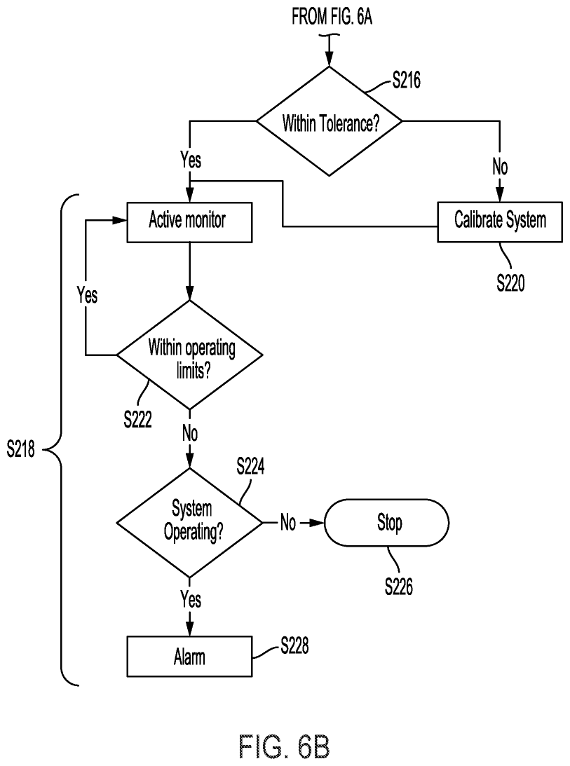

Thus, as illustrated in the flowchart 200 of FIGS. 6A and 6B, operational logic of the system begins by checking at step S202 to see whether the medical equipment 112 being evaluated (device under test, “DUT”) is powered on, e.g., by determining whether the output signal 108′ of the secondary subsystem 100′ is non-zero. If the output signal 108′ is zero, the DUT is not powered on and the processor 106 cycles back (S204) to the initial checking step S202. On the other hand, if the output signal 108′ of the secondary subsystem 100′ is non-zero, the processor 106 evaluates the integrity of the ground connection conductor 122 (S206).

In particular, the processor evaluates whether the output signal 108 from the signal conditioning and amplification circuit 104 is less than a high threshold value (S208), e.g., 50 μA or 500 μA depending on the rating of the associated DUT. If the output signal 108 equals or exceeds the high threshold value, the processor 106 causes an alarm to be issued (S210) as an output signal from the system 100 to indicate that excessive leakage current is being generated. The alarm may be visual (e.g., an LED being illuminated or an error message being caused to be displayed on a monitor or display screen), audible, or both. Additionally, the processor 106 may cause electrical power to the medical equipment 112 under test to be terminated, e.g., by opening a relay in the system 100, causing a switchable outlet to be turned off, etc.

On the other hand, if the output signal 108 from the signal conditioning and amplification circuit 104 is less than the high threshold value, the processor evaluates whether the output signal 108 is greater than a low threshold value (S212), e.g., 10 μA (which is the same for BF and CF-rated medical equipment). If the output signal 108 is less than or equal to the low threshold value, the processor 106 causes an alarm to be issued (S214) as an output signal from the system 100. (Again, the alarm may be visual, audible, or both.) This could happen, for instance, if the ground connection conductor 122 is broken or disconnected (i.e., open circuit), in which case no current—leakage or otherwise—flows through it at all, or if the ground connection conductor 122 is not properly sized, e.g., if it has too high of a resistance to permit the anticipated levels of leakage current to drain to ground through it. And in this case, too, the processor 106 may cause electrical power to the medical equipment 112 under test to be terminated, to prevent it from being used without the safety provided by a ground connection conductor being present.

The threshold values that are applied may vary with the gains associated with the signal conditioning and amplification circuit 104 and/or with the specific DUT being monitored (e.g., if a new DUT is used). Therefore, the threshold values can be calibrated for a given system 100 using known currents in a calibration ground connection conductor line. Furthermore, if the system 100 is provided as a “stand-alone” device or a device that is external to the medical equipment 112 as illustrated in FIGS. 3A and 3B, then the system device may have a switch or setting to toggle the threshold values between those associated with the different equipment rating levels. Further still, in contemplated embodiments of such a stand-alone configuration of the system 100 (not illustrated), the system 100 could be configured to determine automatically the equipment rating—e.g., by a communication link between the DUT and the system 100, an embedded barcode scanner/barcode on the DUT and the system 100, an RFID tag and reader combination, etc.—and configure the threshold values automatically.

Continuing with FIG. 6B, if the operating point of the DUT is within acceptable limits, i.e., if the value of the leakage current flowing within the ground connection conductor 122 is within the high and low thresholds, the processor then determines (at S216) whether the difference, if any, between the currently sensed amount of current within the ground connection conductor 122 and a previously measured amount of current within the ground connection conductor 122 is within a pre-established tolerance.

If the operating point of the DUT is within tolerance relative to the previously stored amount of leakage current, the system 100 switches to an active monitoring mode (S218) in which the processor 106 monitors for significant excursions of current through the ground connection conductor 122. On the other hand, if the operating point of the DUT is not within tolerance relative to the previously stored amount of leakage current, the processor 106 may cause a prompt to be issued for the user or a technician to recalibrate the system 100 (S220), or the system may perform an automatic self-calibration, and the operating point will be stored. Once the system 100 has been recalibrated, the system 100 switches to the active monitoring mode (S218).

In the active monitoring mode S218, the processor 106 repeatedly checks the value of the output signal 108 from the signal conditioning and amplification circuit 104 (S222). If the value of the output signal 108 is within a predetermined range of current values that are expected to be sensed, monitoring continues.

On the other hand, if the value of the output signal 108 is not within the predetermined range of current values that are expected to be sensed, the processor 106 first checks to see whether the medical equipment 112 has stopped operating (S224), e.g., by determining whether the output signal 108′ of the secondary subsystem 100′ has become zero. If the output signal 108′ of the secondary subsystem 100′ has become zero, the DUT is no longer powered on and the process stops (S226). But if the medical equipment 112 has not stopped operating and the value of the output signal 108 is not within the predetermined range of current values that are expected to be sensed—e.g., lower than expected, which could indicate a breakage or other disruption in the ground connection conductor 122, or higher than expected, which could indicate a voltage-to-patient fault condition—the processor causes an alarm to be issued (S228) and may cause power to the medical equipment 112 under test to be terminated. As indicated above, the alarm may be visual (e.g., an LED being illuminated or an error message being caused to be displayed on a monitor or display screen), audible, or both. Moreover, the system may issue different alarms—depending on whether the measured current in the ground connection conductor 122 is higher than or less than the predetermined range of expected current values—so that the user or technician knows the specific cause of the anomaly.

According to a first further embodiment, there is provided a grounding continuity assurance device for use in connection with an electrically powered medical device having a ground connection, including a first current sensor configured to detect and produce a first sensor output signal in response to and indicative of electrical current in a ground connection conductor by which the electrically powered medical device is grounded; and a processor configured to receive a first processor input signal corresponding to the first sensor output signal; wherein the processor is configured to analyze the first processor input signal and issue a first alarm signal if a value of the first processor input signal is less than or equal to a predetermined low threshold value, the predetermined low threshold value corresponding to a minimum level of electrical current expected to be present in the ground connection conductor during normal operation of the electrically powered medical device.

According to a second further embodiment, there is provided the device of the first further embodiment wherein the processor is further configured to analyze the first processor input signal and issue a second alarm signal if the value of the first processor input signal is greater than or equal to a predetermined high threshold value, the predetermined high threshold value corresponding to a maximum level of electrical current expected to be present in the ground connection conductor during normal operation of the electrically powered medical device.

According to a third further embodiment, there is provided the device of any one of the first through second further embodiments, wherein the low threshold value and the high threshold value correspond to a rating of the electrically powered medical device, the rating being based on whether the electrically powered medical device makes direct electrical contact with a patient's heart.

According to a fourth further embodiment, there is provided the device of any one of the first through third further embodiments, wherein the low threshold value and the high threshold value are switchable to different values to facilitate use of the grounding continuity assurance device with electrically powered medical devices having different ratings.

According to a fifth further embodiment, there is provided the device of any one of the first through fourth further embodiments, wherein the first sensor output signal constitutes electrical current and the first processor input signal constitutes voltage, and wherein the grounding continuity assurance device further comprises signal-processing circuitry configured to receive as input thereto the first sensor output signal and to output, as said first processor input signal, a voltage corresponding to the first sensor output signal.

According to a sixth further embodiment, there is provided the device of any one of the first through fifth further embodiments, wherein the first current sensor comprises a transformer with a ring-shaped, magnetic flux-conducting core, a primary conductor coil looped around a first portion of the magnetic flux-conducting core, and a secondary conductor coil looped around a second portion of the magnetic flux-conducting core, with the primary conductor coil being formed by a portion of the ground connection conductor and with the first sensor output signal constituting electrical current induced in the secondary conductor coil by alternating current flowing along the ground connection conductor.

According to a seventh further embodiment, there is provided the device of any one of the first through sixth further embodiments, wherein the signal-processing circuitry comprises a gain stage.

According to an eighth further embodiment, there is provided the device of any one of the first through seventh further embodiments, wherein the signal-processing circuitry comprises a rectification and peak-picking stage.

According to a ninth further embodiment, there is provided the device of any one of the first through eighth further embodiments, further including a second current sensor configured to detect and produce a second sensor output signal in response to and indicative of electrical current in an AC load line that provides electrical power to the electrically powered medical device, wherein the processor is further configured to receive a second processor input signal corresponding to the second sensor output signal; and wherein the processor is configured to analyze the second processor input signal to determine whether the electrically powered medical device is powered on before analyzing the first processor input signal to determine whether the value of the first processor input signal is less than or equal to the predetermined low threshold value.

According to a tenth further embodiment, there is provided the device of any one of the first through ninth further embodiments, wherein the processor is further configured to analyze the first processor input signal and issue a third alarm signal if the value of the first processor input signal corresponds to a voltage-to-patient fault condition.

According to an eleventh further embodiment, there is provided the device of any one of the first through tenth further embodiments, wherein the grounding continuity assurance device comprises a stand-alone device that is configured to be interposed between a source of electrical power and the electrically powered medical device, with electrical current passing through the grounding continuity assurance device between the source of electrical power and the electrically powered medical device.

According to a twelfth further embodiment, there is provided the device of any one of the first through eleventh further embodiments, wherein the grounding continuity assurance device is integral with the electrically powered medical device.

According to a thirteenth further embodiment, there is provided the device of any one of the first through twelfth further embodiments, wherein the grounding continuity assurance device is configured to terminate or prevent flow of electricity to the electrically powered medical device if the value of the first processor input signal is less than or equal to the predetermined low threshold value.

According to a fourteenth further embodiment, there is provided the device of any one of the first through thirteenth further embodiments, wherein the grounding continuity assurance device is configured to terminate or prevent flow of electricity to the electrically powered medical device if the value of the first processor input signal is greater than or equal to the predetermined high threshold value.

According to a fifteenth further embodiment, there is provided the device of any one of the first through fourteenth further embodiments, wherein the grounding continuity assurance device is configured to terminate or prevent flow of electricity to the electrically powered medical device if the value of the first processor input signal corresponds to the voltage-to-patient fault condition.

According to a sixteenth further embodiment, there is provided a method for assuring safety of a patient being treated with electrically powered medical device that is grounded via a ground connection conductor, the method including sensing current level in the ground connection conductor in a first sensing phase; and issuing a first alarm signal if the current level in the ground connection conductor during the first sensing phase is less than or equal to a predetermined low threshold value, the predetermined low threshold value corresponding to a minimum level of electrical current expected to be present in the ground connection conductor during normal operation of the electrically powered medical device.

According to a seventeenth further embodiment, there is provided the method of the sixteenth further embodiment, further including issuing a second alarm signal if the current level in the ground connection conductor during the first sensing phase is greater than or equal to a predetermined high threshold value, the predetermined high threshold value corresponding to a maximum level of electrical current expected to be present in the ground connection conductor during normal operation of the electrically powered medical device.

According to an eighteenth further embodiment, there is provided the method of any one of the sixteenth through seventeenth further embodiments, further including sensing current level in the ground connection conductor in a second sensing phase after the first sensing phase, and issuing a third alarm signal if the current level in the ground connection conductor during the second sensing phase corresponds to a voltage-to-patient fault condition.

According to a nineteenth further embodiment, there is provided the method of any one of the sixteenth through eighteenth further embodiments, further including sensing current level in a load line that provides electrical power to the medical device prior to said first sensing phase, to determine whether the medical device is powered on and requires monitoring.

According to a twentieth further embodiment, there is provided the method of any one of the sixteenth through nineteenth further embodiments, further including terminating or preventing flow of electricity to the electrically powered medical device if a value of the current level is less than or equal to the predetermined low threshold value.

According to a twenty-first further embodiment, there is provided the method of any one of the sixteenth through twentieth further embodiments, further including terminating or preventing flow of electricity to the electrically powered medical device if a value of the current level is greater than or equal to the predetermined high threshold value.

According to a twenty-second further embodiment, there is provided the method of any one of the sixteenth through twenty-first further embodiments, further including terminating or preventing flow of electricity to the electrically powered medical device if the current level in the ground connection conductor during the second sensing phase corresponds to the voltage-to-patient fault condition.

According to a twenty-third further embodiment, there is provided a grounding continuity assurance device for use in connection with an electrically powered medical device having a ground connection, including a first current sensor configured to detect and produce a first sensor output signal in response to and indicative of electrical current in a ground connection conductor by which the electrically powered medical device is grounded; and a processor configured to receive a first processor input signal corresponding to the first sensor output signal; wherein the processor is configured to analyze the first processor input signal and issue a first alarm signal if a value of the first processor input signal is less than or equal to a predetermined low threshold value, the predetermined low threshold value corresponding to a minimum level of electrical current expected to be present in the ground connection conductor during normal operation of the electrically powered medical device.

According to a twenty-fourth further embodiment, there is provided the grounding continuity assurance device of the twenty-third further embodiment, wherein the processor is further configured to analyze the first processor input signal and issue a second alarm signal if the value of the first processor input signal is greater than or equal to a predetermined high threshold value, the predetermined high threshold value corresponding to a maximum level of electrical current expected to be present in the ground connection conductor during normal operation of the electrically powered medical device.

According to a twenty-fifth further embodiment, there is provided the grounding continuity assurance device of any one of the twenty-third through twenty-fourth further embodiments, wherein the low threshold value and the high threshold value correspond to a rating of the electrically powered medical device, the rating being based on whether the electrically powered medical device makes direct electrical contact with a patient's heart.

According to a twenty-sixth further embodiment, there is provided the grounding continuity assurance device of any one of the twenty-third through twenty-fifth further embodiments, wherein the low threshold value and the high threshold value are switchable to different values to facilitate use of the grounding continuity assurance device with electrically powered medical devices having different ratings.

According to a twenty-seventh further embodiment, there is provided the grounding continuity assurance device of any one of the twenty-third through twenty-sixth further embodiments, wherein the first sensor output signal constitutes electrical current and the first processor input signal constitutes voltage, and wherein the grounding continuity assurance device further comprises signal-processing circuitry configured to receive as input thereto the first sensor output signal and to output, as said first processor input signal, a voltage corresponding to the first sensor output signal.

According to a twenty-eighth further embodiment, there is provided the grounding continuity assurance device of any one of the twenty-third through twenty-seventh further embodiments, wherein the first current sensor comprises a transformer with a ring-shaped, magnetic flux-conducting core, a primary conductor coil looped around a first portion of the magnetic flux-conducting core, and a secondary conductor coil looped around a second portion of the magnetic flux-conducting core, with the primary conductor coil being formed by a portion of the ground connection conductor and with the first sensor output signal constituting electrical current induced in the secondary conductor coil by alternating current flowing along the ground connection conductor.

According to a twenty-ninth further embodiment, there is provided the grounding continuity assurance device of any one of the twenty-third through twenty-eighth further embodiments, wherein the signal-processing circuitry comprises a gain stage.

According to a thirtieth further embodiment, there is provided the grounding continuity assurance device of any one of the twenty-third through twenty-ninth further embodiments, wherein the signal-processing circuitry comprises a rectification and peak-picking stage.

According to a thirty-first further embodiment, there is provided the grounding continuity assurance device of any one of the twenty-third through thirtieth further embodiments, further including a second current sensor configured to detect and produce a second sensor output signal in response to and indicative of electrical current in an AC load line that provides electrical power to the electrically powered medical device, wherein the processor is further configured to receive a second processor input signal corresponding to the second sensor output signal; and wherein the processor is configured to analyze the second processor input signal to determine whether the electrically powered medical device is powered on before analyzing the first processor input signal to determine whether the value of the first processor input signal is less than or equal to the predetermined low threshold value.

According to a thirty-second further embodiment, there is provided the grounding continuity assurance device of any one of the twenty-third through thirty-first further embodiments, wherein the processor is further configured to analyze the first processor input signal and issue a third alarm signal if the value of the first processor input signal corresponds to a voltage-to-patient fault condition.

According to a thirty-third further embodiment, there is provided the grounding continuity assurance device of any one of the twenty-third through thirty-second further embodiments, wherein the grounding continuity assurance device comprises a stand-alone device that is configured to be interposed between a source of electrical power and the electrically powered medical device, with electrical current passing through the grounding continuity assurance device between the source of electrical power and the electrically powered medical device.

According to a thirty-fourth further embodiment, there is provided the grounding continuity assurance device of any one of the twenty-third through thirty-third further embodiments, wherein the grounding continuity assurance device is integral with the electrically powered medical device.

According to a thirty-fifth further embodiment, there is provided the grounding continuity assurance device of any one of the twenty-third through thirty-fourth further embodiments, wherein the grounding continuity assurance device is configured to terminate or prevent flow of electricity to the electrically powered medical device if the value of the first processor input signal is less than or equal to the predetermined low threshold value.

According to a thirty-sixth further embodiment, there is provided the grounding continuity assurance device of any one of the twenty-third through thirty-fifth further embodiments, wherein the grounding continuity assurance device is configured to terminate or prevent flow of electricity to the electrically powered medical device if the value of the first processor input signal is greater than or equal to the predetermined high threshold value.

According to a thirty-seventh further embodiment, there is provided the grounding continuity assurance device of any one of the twenty-third through thirty-sixth further embodiments, wherein the grounding continuity assurance device is configured to terminate or prevent flow of electricity to the electrically powered medical device if the value of the first processor input signal corresponds to the voltage-to-patient fault condition.

According to a thirty-eighth further embodiment, there is provided a method for assuring safety of a patient being treated with electrically powered medical device that is grounded via a ground connection conductor, the method including sensing current level in the ground connection conductor in a first sensing phase; and issuing a first alarm signal if the current level in the ground connection conductor during the first sensing phase is less than or equal to a predetermined low threshold value, the predetermined low threshold value corresponding to a minimum level of electrical current expected to be present in the ground connection conductor during normal operation of the electrically powered medical device.

According to a thirty-ninth further embodiment, there is provided the method of the thirty-eighth further embodiment, further including issuing a second alarm signal if the current level in the ground connection conductor during the first sensing phase is greater than or equal to a predetermined high threshold value, the predetermined high threshold value corresponding to a maximum level of electrical current expected to be present in the ground connection conductor during normal operation of the electrically powered medical device.

According to a fortieth further embodiment, there is provided the method of any one of the thirty-eighth through thirty-ninth further embodiments, further including sensing current level in the ground connection conductor in a second sensing phase after the first sensing phase, and issuing a third alarm signal if the current level in the ground connection conductor during the second sensing phase corresponds to a voltage-to-patient fault condition.

According to a forty-first further embodiment, there is provided the method of any one of the thirty-eighth through fortieth further embodiments, further including sensing current level in a load line that provides electrical power to the medical device prior to said first sensing phase, to determine whether the medical device is powered on and requires monitoring.

According to a forty-second further embodiment, there is provided the method of any one of the thirty-eighth through forty-first further embodiments, further including terminating or preventing flow of electricity to the electrically powered medical device if a value of the current level is less than or equal to the predetermined low threshold value.

According to a forty-third further embodiment, there is provided the method of any one of the thirty-eighth through forty-second further embodiments, further including terminating or preventing flow of electricity to the electrically powered medical device if a value of the current level is greater than or equal to the predetermined high threshold value.

According to a forty-fourth further embodiment, there is provided the method of any one of the thirty-eighth through forty-third further embodiments, further including terminating or preventing flow of electricity to the electrically powered medical device if the current level in the ground connection conductor during the second sensing phase corresponds to the voltage-to-patient fault condition.

According to a forty-fifth further embodiment, there is provided a medical device configured to provide a treatment to a patient, including a connection from the medical device to the patient that establishes an electrical current path between the medical device and the patient; a conductive connection to an electrical ground; and a grounding continuity assurance device that includes a first current sensor configured to detect and produce a first sensor output signal in response to and indicative of electrical current in the conductive connection to the electrical ground; and a processor configured to receive a first processor input signal corresponding to the first sensor output signal, wherein the processor is configured to analyze the first processor input signal and issue a first alarm signal if a value of the first processor input signal is less than or equal to a predetermined low threshold value, the predetermined low threshold value corresponding to a minimum level of electrical current expected to be present in the conductive connection to the electrical ground during normal operation of the medical device.

According to a forty-sixth further embodiment, there is provided the medical device of the forty-fifth further embodiment, wherein the processor is further configured to analyze the first processor input signal and issue a second alarm signal if the value of the first processor input signal is greater than or equal to a predetermined high threshold value, the predetermined high threshold value corresponding to a maximum level of electrical current expected to be present in the conductive connection to the electrical ground during normal operation of the medical device.

According to a forty-seventh further embodiment, there is provided the medical device of any one of the forty-fifth through forty-sixth further embodiments, wherein the low threshold value and the high threshold value correspond to a rating of the medical device, the rating being based on whether the medical device makes direct electrical contact with a patient's heart.

According to a forty-eighth further embodiment, there is provided the medical device of any one of the forty-fifth through forty-seventh further embodiments, wherein the low threshold value and the high threshold value are switchable to different values to facilitate use of the medical device with medical devices having different ratings.

According to a forty-ninth further embodiment, there is provided the medical device of any one of the forty-fifth through forty-eighth further embodiments, wherein the first sensor output signal constitutes electrical current and the first processor input signal constitutes voltage, and wherein the medical device further comprises signal-processing circuitry configured to receive as input thereto the first sensor output signal and to output, as said first processor input signal, a voltage corresponding to the first sensor output signal.

According to a fiftieth further embodiment, there is provided the medical device of any one of the forty-fifth through forty-ninth further embodiments, wherein the first current sensor comprises a transformer with a ring-shaped, magnetic flux-conducting core, a primary conductor coil looped around a first portion of the magnetic flux-conducting core, and a secondary conductor coil looped around a second portion of the magnetic flux-conducting core, with the primary conductor coil being formed by a portion of the conductive connection to the electrical ground and with the first sensor output signal constituting electrical current induced in the secondary conductor coil by alternating current flowing along the conductive connection to the electrical ground.

According to a fifty-first further embodiment, there is provided the medical device of any one of the forty-fifth through fiftieth further embodiments, wherein the signal-processing circuitry comprises a gain stage.

According to a fifty-second further embodiment, there is provided the medical device of any one of the forty-fifth through fifty-first further embodiments, wherein the signal-processing circuitry comprises a rectification and peak-picking stage.

According to a fifty-third further embodiment, there is provided the medical device of any one of the forty-fifth through fifty-second further embodiments, wherein the signal-processing circuitry comprises an offset-shifting stage.

According to a fifty-fourth further embodiment, there is provided the medical device of any one of the forty-fifth through fifty-third further embodiments, further including a second current sensor configured to detect and produce a second sensor output signal in response to and indicative of electrical current in an AC load line that provides electrical power to the medical device, wherein the processor is further configured to receive a second processor input signal corresponding to the second sensor output signal; and wherein the processor is configured to analyze the second processor input signal to determine whether the medical device is powered on before analyzing the first processor input signal to determine whether the value of the first processor input signal is less than or equal to the predetermined low threshold value.

According to a fifty-fifth further embodiment, there is provided the medical device of any one of the forty-fifth through fifty-fourth further embodiments, wherein the processor is further configured to analyze the first processor input signal and issue a third alarm signal if the value of the first processor input signal corresponds to a voltage-to-patient fault condition.

According to a fifty-sixth further embodiment, there is provided the medical device of any one of the forty-fifth through fifty-fifth further embodiments, wherein the medical device comprises a stand-alone device that is configured to be interposed between a source of electrical power and the medical device, with electrical current passing through the medical device between the source of electrical power and the medical device.

According to a fifty-seventh further embodiment, there is provided the medical device of any one of the forty-fifth through fifty-sixth further embodiments, wherein the grounding continuity assurance device is integral with the medical device.

According to a fifty-eighth further embodiment, there is provided the medical device of any one of the forty-fifth through fifty-seventh further embodiments, wherein the grounding continuity assurance device is configured to terminate or prevent flow of electricity to the medical device if the value of the first processor input signal is less than or equal to the predetermined low threshold value.

According to a fifty-ninth further embodiment, there is provided the medical device of any one of the forty-fifth through fifty-eighth further embodiments, wherein the grounding continuity assurance device is configured to terminate or prevent flow of electricity to the medical device if the value of the first processor input signal is greater than or equal to the predetermined high threshold value.

According to a sixtieth further embodiment, there is provided the medical device of any one of the forty-fifth through fifty-ninth further embodiments, wherein the grounding continuity assurance device is configured to terminate or prevent flow of electricity to the medical device if the value of the first processor input signal corresponds to the voltage-to-patient fault condition.

Thus, it is apparent that there is provided, in accordance with the present disclosure, a system and method for assuring that electrically powered medical devices are properly grounded, as well as for detecting whether a voltage-to-patient fault has occurred. Many alternatives, modifications, and variations are enabled by the present disclosure. Features of the disclosed embodiments can be combined, rearranged, omitted, etc., within the scope of the invention to produce additional embodiments. Furthermore, certain features may sometimes be used to advantage without a corresponding use of other features. Accordingly, Applicants intend to embrace all such alternatives, modifications, equivalents, and variations that are within the spirit and scope of the present disclosure.

What is claimed is:

1. A grounding continuity assurance device for use in connection with an electrically powered medical device having a ground connection, comprising:
a first current sensor configured to detect and produce a first sensor output signal in response to and indicative of electrical current in a ground connection conductor by which the electrically powered medical device is grounded; and
a processor configured to receive a first processor input signal corresponding to the first sensor output signal;
wherein the processor is configured to analyze the first processor input signal and issue a first alarm signal if a value of the first processor input signal is less than or equal to a predetermined low threshold value, the predetermined low threshold value corresponding to a minimum level of electrical current expected to be present in the ground connection conductor during normal operation of the electrically powered medical device.

2. The grounding continuity assurance device according to claim 1, wherein the processor is further configured to analyze the first processor input signal and issue a second alarm signal if the value of the first processor input signal is greater than or equal to a predetermined high threshold value, the predetermined high threshold value corresponding to a maximum level of electrical current expected to be present in the ground connection conductor during normal operation of the electrically powered medical device.

3. The grounding continuity assurance device according to claim 2, wherein the low threshold value and the high threshold value correspond to a rating of the electrically powered medical device, the rating being based on whether the electrically powered medical device makes direct electrical contact with a patient's heart.

4. The grounding continuity assurance device according to claim 3, wherein the low threshold value and the high threshold value are switchable to different values to facilitate use of the grounding continuity assurance device with electrically powered medical devices having different ratings.

5. The grounding continuity assurance device according to claim 1, wherein the first sensor output signal constitutes electrical current and the first processor input signal constitutes voltage, and
wherein the grounding continuity assurance device further comprises signal-processing circuitry configured to receive as input thereto the first sensor output signal and to output, as said first processor input signal, a voltage corresponding to the first sensor output signal.

6. The grounding continuity assurance device according to claim 5, wherein the first current sensor comprises a transformer with a ring-shaped, magnetic flux-conducting core, a primary conductor coil looped around a first portion of the magnetic flux-conducting core, and a secondary conductor coil looped around a second portion of the magnetic flux-conducting core, with the primary conductor coil being formed by a portion of the ground connection conductor and with the first sensor output signal constituting electrical current induced in the secondary conductor coil by alternating current flowing along the ground connection conductor.

7. The grounding continuity assurance device according to claim 5, wherein the signal-processing circuitry comprises a gain stage.

8. The grounding continuity assurance device according to claim 5, wherein the signal-processing circuitry comprises a rectification and peak-picking stage.

9. The grounding continuity assurance device according to claim 1, further comprising a second current sensor configured to detect and produce a second sensor output signal in response to and indicative of electrical current in an AC load line that provides electrical power to the electrically powered medical device,
wherein the processor is further configured to receive a second processor input signal corresponding to the second sensor output signal; and
wherein the processor is configured to analyze the second processor input signal to determine whether the electrically powered medical device is powered on before analyzing the first processor input signal to determine whether the value of the first processor input signal is less than or equal to the predetermined low threshold value.

10. The grounding continuity assurance device according to claim 1, wherein the processor is further configured to analyze the first processor input signal and issue a third alarm signal if the value of the first processor input signal corresponds to a voltage-to-patient fault condition.

11. The grounding continuity assurance device according to claim 1, wherein the grounding continuity assurance device comprises a stand-alone device that is configured to be interposed between a source of electrical power and the electrically powered medical device, with electrical current passing through the grounding continuity assurance device between the source of electrical power and the electrically powered medical device.

12. The grounding continuity assurance device according to claim 1, wherein the grounding continuity assurance device is integral with the electrically powered medical device.

13. The grounding continuity assurance device according to claim 1, wherein the grounding continuity assurance device is configured to terminate or prevent flow of electricity to the electrically powered medical device if the value of the first processor input signal is less than or equal to the predetermined low threshold value.

14. The grounding continuity assurance device according to claim 2, wherein the grounding continuity assurance device is configured to terminate or prevent flow of electricity to the electrically powered medical device if the value of the first processor input signal is greater than or equal to the predetermined high threshold value.

15. The grounding continuity assurance device according to claim 10, wherein the grounding continuity assurance device is configured to terminate or prevent flow of electricity to the electrically powered medical device if the value of the first processor input signal corresponds to the voltage-to-patient fault condition.

16. A method for assuring safety of a patient being treated with electrically powered medical device that is grounded via a ground connection conductor, the method comprising:
sensing current level in the ground connection conductor in a first sensing phase; and
issuing a first alarm signal if the current level in the ground connection conductor during the first sensing phase is less than or equal to a predetermined low threshold value, the predetermined low threshold value corresponding to a minimum level of electrical current expected to be present in the ground connection conductor during normal operation of the electrically powered medical device.

17. The method according to claim 16, further comprising issuing a second alarm signal if the current level in the ground connection conductor during the first sensing phase is greater than or equal to a predetermined high threshold value, the predetermined high threshold value corresponding to a maximum level of electrical current expected to be present in the ground connection conductor during normal operation of the electrically powered medical device.

18. The method according to claim 17, further comprising sensing current level in the ground connection conductor in a second sensing phase after the first sensing phase, and
issuing a third alarm signal if the current level in the ground connection conductor during the second sensing phase corresponds to a voltage-to-patient fault condition.

19. The method according to claim 16, further comprising sensing current level in a load line that provides electrical power to the medical device prior to said first sensing phase, to determine whether the medical device is powered on and requires monitoring.

20. The method according to claim 16, further comprising terminating or preventing flow of electricity to the electrically powered medical device if a value of the current level is less than or equal to the predetermined low threshold value.
